(19) United States
(12) Patent Application Publication
(10) Pub. No.: US 2026/0119740 A1
(43) Pub. Date: Apr. 30, 2026

(54) APPARATUS AND METHOD FOR EVALUATING DIGITAL TWINS

(71) Applicant: Electronics and Telecommunications Research Institute, Daejeon (KR)

(72) Inventors: Yong Woon KIM, Daejeon (KR); Sung Hei KIM, Daejeon (KR); Hak Suh KIM, Daejeon (KR); Kyoung Jae SUN, Daejeon (KR); Sang Keun YOO, Daejeon (KR); Chang Kyu LEE, Daejeon (KR); Hyun Jeong LEE, Daejeon (KR); Shin Gak KANG, Daejeon (KR); Jun Seob LEE, Daejeon (KR)

(73) Assignee: Electronics and Telecommunications Research Institute, Daejeon (KR)

(21) Appl. No.: 19/368,701

(22) Filed: Oct. 24, 2025

(30) Foreign Application Priority Data
Oct. 25, 2024 (KR) 10-2024-0147943
Oct. 23, 2025 (KR) 10-2025-0154517

(51) Int. Cl. G06F 30/20

(52) U.S. Cl. CPC G06F 30/20

(57) ABSTRACT

The present invention relates to an apparatus and method for evaluating digital twins. The apparatus for evaluating digital twins includes a memory configured to store at least one instruction, and a processor configured to execute the at least one instruction stored in the memory, in which the processor acquires evaluation values of each evaluation item in a state in which a plurality of evaluation indicators and a plurality of evaluation items related to each of the plurality of evaluation indicators are defined, and calculates a quality assurance index, which is defined as an index quantitatively representing the quality of a target digital twin to be evaluated, based on the evaluation values of each evaluation item.

### CROSS-REFERENCE TO RELATED APPLICATION

This application claims priority to and the benefit of Korean Patent Application No. 10-2024-0147943, filed on Oct. 25, 2024, and Korean Patent Application No. 10-2025-0154517, filed on Oct. 23, 2025, the disclosures of which are incorporated herein by reference in their entirety.

### BACKGROUND

### 1. Field of the Invention

The present invention relates to an apparatus and method for evaluating digital twins, and more particularly, to an apparatus and method for evaluating digital twins capable of quantitatively evaluating the quality of digital twins.

### 2. Discussion of Related Art

Digital twins are a technology that replicates real-world physical objects in a virtual space for simulation, monitoring, prediction, etc. In recent years, digital twins have been utilized in a variety of industry fields. To develop such digital twins, it is necessary to specifically identify objects to be modeled based on the requirements derived from the purpose and utilization plan of the digital twins and to design and implement a digital twin model to satisfy the specified requirements.

The quality of the digital twins refers to how closely the digital twins embody the actual physical objects. The quality of the digital twins may vary not only depending on a developer's experience and technological capability, but also on development project management and operational methods, such as development time, development manpower, and stakeholder engagement level.

In the past, there was no systematic method of quantitatively evaluating the quality of digital twins, and thus qualitative evaluation was relied on to determine the quality of digital twins. Accordingly, there is a need for a technology capable of quantitatively evaluating the quality of digital twins.

### SUMMARY OF THE INVENTION

The present invention is directed to providing an apparatus and method for evaluating digital twins capable of quantitatively evaluating how well a digital twin, as a development outcome, corresponds to the original intention and utilization plan of a project client for whom the corresponding digital twin is developed.

According to an aspect of the present invention, there is provided an apparatus for evaluating digital twins, including: a memory configured to store at least one instruction; and a processor configured to execute the at least one instruction stored in the memory, in which the processor acquires evaluation values of each evaluation item in a state in which a plurality of evaluation indicators and a plurality of evaluation items related to each of the plurality of evaluation indicators are defined, and calculates a quality assurance index, which is defined as an index quantitatively representing the quality of a target digital twin to be evaluated, based on the evaluation values of each evaluation item.

The processor may perform, for each of the plurality of evaluation indicators, an operation of calculating an indicator value of the target evaluation indicator based on the evaluation values of each of the plurality of evaluation items related to the target evaluation indicator, and calculate the quality assurance index based on the indicator values of each of the plurality of evaluation items.

The plurality of evaluation indicators may include a similarity representing a degree to which the target digital twin corresponds to the corresponding physical object based on overall characteristics, correspondence representing a degree to which the target digital twin corresponds to the physical object based on a specific element, and fidelity representing a degree to which the target digital twin corresponds to the physical object based on detailed characteristics.

The processor may acquire configuration information regarding a representation form of the evaluation indicator, a representation form of the quality assurance index, whether to assign a weight to the evaluation item when calculating the evaluation indicator, and whether to assign a weight to the evaluation indicator when calculating the quality assurance index, and calculate the quality assurance index in consideration of the configuration information.

The indicator value of the evaluation indicator may be expressed in either a first form in which the evaluation values of each of the plurality of evaluation items related to the evaluation indicator are listed, or a second form in which the evaluation values of each of the plurality of evaluation items related to the evaluation indicator are expressed as a unified representative value.

When it is necessary to assign the weight to the evaluation item, the processor may assign a predefined weight to each of the plurality of evaluation items related to the target evaluation indicator and calculate an indicator value of the target evaluation indicator based on the evaluation values to which the weights are assigned.

When it is necessary to express the evaluation indicator in the second form and it is necessary to assign the weight to the evaluation item, the processor may calculate the indicator value of the target evaluation indicator based on at least one of a weighted sum, a weighted arithmetic mean, a weighted geometric mean, and a weighted harmonic mean of the evaluation values of each of the plurality of evaluation items related to the target evaluation indicator.

When it is necessary to express the evaluation indicator in the second form and it is not necessary to assign the weight to the evaluation item, the processor may calculate the indicator value of the target evaluation indicator based on at least one of a simple sum, an arithmetic mean, a geometric mean, a harmonic mean, a root mean square, a minimum value, a maximum value, and an index mean of the evaluation values of each of the plurality of evaluation items related to the target evaluation indicator.

The quality assurance index may be expressed in either a first form in which the indicator values of each of the plurality of evaluation indicators are listed, or a second form in which the indicator values of each of the plurality of evaluation indicators are expressed as a unified representative value.

When it is necessary to assign the weight to the evaluation indicator, the processor may assign a predefined weight to the indicator values of each of the plurality of evaluation indicators, and calculate the quality assurance index based on the indicator values to which the weights are assigned.

According to another aspect of the present invention, there is provided a method of evaluating digital twins, including: acquiring, by a processor, evaluation values of each of a plurality of evaluation items in a state in which a plurality of evaluation indicators and a plurality of evaluation items related to each of the plurality of evaluation indicators are defined; and calculating, by the processor, a quality assurance index defined as an index that quantitatively represents the quality of the target digital twin to be evaluated, based on the evaluation values of each evaluation item.

According to one aspect of the present invention, it is possible to quantitatively and objectively evaluate the quality of the digital twins and provide the evaluation results to the user.

According to one aspect of the present invention, by evaluating the quality of the digital twin based on the clear and systematic criteria, it is possible to enhance the reliability of the evaluation results of the digital twin.

According to one aspect of the present invention, by adjusting the evaluation indicators used in evaluating the digital twins in accordance with the development purpose of the digital twins and the requirements of the project for developing the digital twins, it is possible to clearly verify whether the digital twins meet the expected objectives of the project client.

According to one aspect of the present invention, by calculating the evaluation indicators and quality assurance indices in various ways when evaluating the quality of the digital twins, it is possible to optimize the method of evaluating digital twins.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram illustrating an apparatus for evaluating digital twins according to an embodiment of the present invention;

FIG. 2 is an exemplary diagram illustrating evaluation indicators and evaluation items;

FIG. 3 is an exemplary diagram illustrating a representation form of the evaluation indicators;

FIG. 4 is an exemplary diagram illustrating a type of quality assurance indices according to conditions; and

FIG. 5 is a flowchart illustrating a method of evaluating digital twins according to an embodiment of the present invention

### DETAILED DESCRIPTION OF EXEMPLARY EMBODIMENTS

Hereinafter, embodiments of an apparatus and method for evaluating digital twins according to the present invention will be described with reference to the accompanying drawings. In this process, thicknesses of lines, sizes of components, and the like illustrated in the accompanying drawings may be exaggerated for clearness of explanation and convenience. In addition, terms to be described below are defined in consideration of functions in the present invention and may be construed in different ways according to the intentions of users or practice. Therefore, these terms should be defined on the basis of the content throughout the present specification.

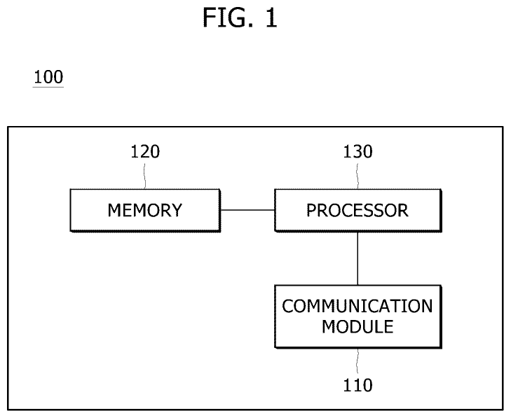

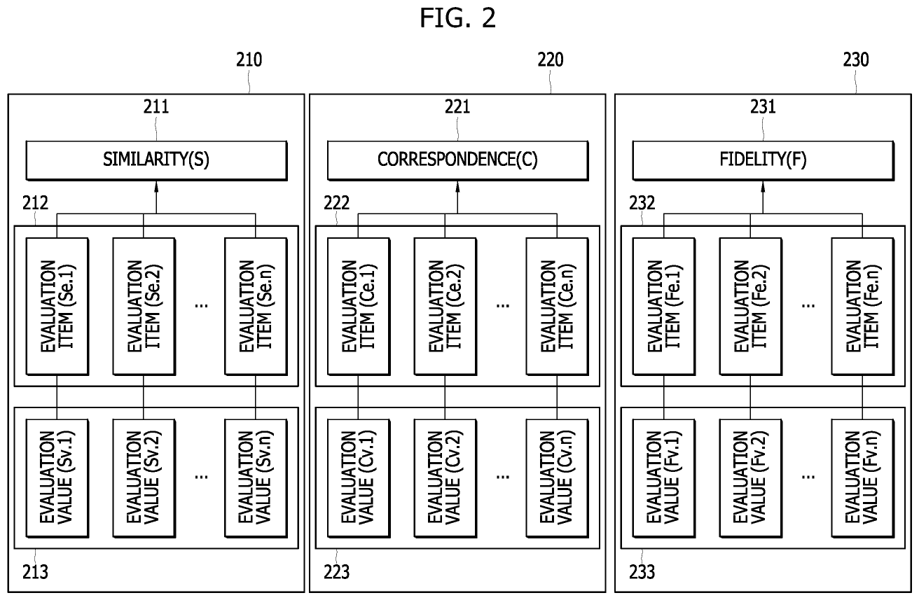

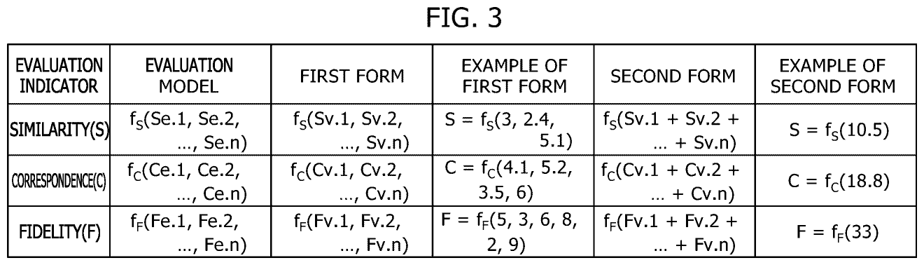

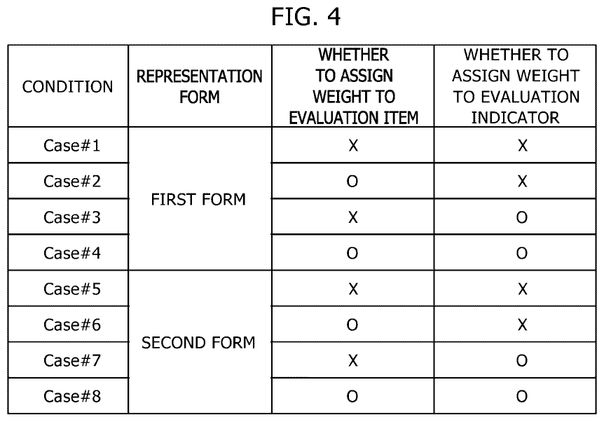

FIG. 1 is a block diagram illustrating an apparatus for evaluating digital twins according to an embodiment of the present invention, FIG. 2 is an exemplary diagram illustrating evaluation indicators and evaluation items, FIG. 3 is an exemplary diagram illustrating a representation form of the evaluation indicators, and FIG. 4 is an exemplary diagram illustrating a type of quality assurance indices according to conditions.

Referring to FIG. 1, an apparatus 100 for evaluating digital twins according to an embodiment of the present invention may include a communication module 110, a memory 120, and a processor 130. The apparatus 100 for evaluating digital twins according to an embodiment of the present invention may further include various components in addition to the components illustrated in FIG. 1. In various embodiments, the apparatus 100 for evaluating digital twins according to an embodiment of the present invention may include an input interface for receiving information (e.g., evaluation items, evaluation values of each item, etc.) required during a process of evaluating the digital twins to be evaluated from a user. The input interface may include a keyboard, a touchscreen, a digitizer, etc., and the user may input various pieces of information required during the process of evaluating the digital twins using the keyboard, touchscreen, digitizer, etc.

The communication module 110 may communicate with an external device. The communication module 110 may communicate with various types of external devices depending on various types of communication manners. The communication module 110 may acquire various pieces of information (e.g., evaluation items, evaluation values of each evaluation item, etc.) required during the process of evaluating the digital twins (hereinafter, the target digital twins) to be evaluated from an external device (e.g., a server or database). The evaluation items and evaluation values of each evaluation item may be determined in a predefined manner (e.g., a survey, etc.) and stored in the external device. The evaluation items and evaluation values of each evaluation item stored in the external device may also be modified by the user.

According to an embodiment, the communication module 110 may receive digital twin data (e.g., state vector x(t), predicted trajectory, virtual sensor output, event) by subscribing to state data published by the runtime of the target digital twin in a pub/sub manner. For example, the communication module 110 may subscribe to a frame including a schema identifier (SchemaID), a model revision identifier (RevID), an epoch identifier (EpochID), a timestamp (ts), a sequence number (seq), and a payload using a protocol such as OPC UA PubSub, DDS/ROS 2, or MQTT, and may receive data in a reliable mode (QoS: at least one or exactly one transmission) when a synchronization error in gPTP-based time synchronization is less than or equal to a predetermined threshold (e.g., 1 ms). Delta encoding and optional compression may be applied to the payload, and the communication module 110 may reverse-transform the payload to restore the state vector of the digital twin. In addition, the communication module 110 may verify the signature or checksum of the received frame, and may transmit only frames that satisfy the conditions of timestamp drift and monotonically increasing sequence to the processor 130 to be utilized in the evaluation described below.

In another embodiment, when the digital twin runtime operates as a separate process/thread within the same device, the communication module 110 may acquire frames from a circular buffer mapped to shared memory according to a polling cycle T, exclude torn frames using a header's sequence number and checksum, and then perform the same inverse transformation-verification procedures described above.

The digital twin data received in this manner may be mapped to design data via an entity key (EntityID, part number, etc.) and used to calculate evaluation values of each evaluation item. The input pipeline composed of reception-verification-buffering-inverse transformation may support the apparatus for evaluating digital twins in efficiently performing evaluation tasks.

The memory 120 may store basic data required during the process of evaluating the target digital twin or data generated during the process of evaluating the target digital twin. The processor 130 may perform an operation of accessing data stored in the memory 120 to evaluate the target digital twin.

The memory 120 may be implemented as a computer-readable recording medium and may be operable to be accessed by the processor 130. Specifically, the memory 120 may be implemented as a hard drive, a magnetic tape, a memory card, a read-only memory (ROM), a random-access memory (RAM), a digital video disc (DVD), or an optical data storage device such as an optical disc.

The processor 130 is an entity that performs the process of evaluating the target digital twin and may be implemented as an application-specific integrated circuit (ASIC), a digital signal processor (DSP), a programmable logic device (PLD), field-programmable gate arrays (FPGAs), a central processing unit (CPU), a microcontroller, and/or a microprocessor, and may run an operating system or application and control multiple hardware or software components. The processor 130 may be configured to execute at least one command stored in the memory 120 and store the execution result data in the memory 120.

The processor 130 may acquire the evaluation values of each of the predefined evaluation items and calculate a quality assurance index of the target digital twin based on the evaluation values of each of the acquired evaluation items. In the present embodiment, the quality assurance index may be a value obtained by quantitatively evaluating the quality of the digital twin. The quality assurance index may indicate the extent to which the digital twin satisfies the development purpose, utilization plan, and corresponding requirements intended by the project owner for the development of the corresponding digital twin. A high quality assurance index of the target digital twin may mean that the target digital twin has achieved a high quality level. The quality assurance index may also be referred to as a quality index, a quality evaluation index, or a quality level index. Although the names may differ, the result of evaluating the quality of the digital twin may be interpreted as being included in the quality assurance index of the present embodiment.

The evaluation values of each evaluation item may be calculated and stored in a server or database through measurement or quantification of each evaluation item in advance. The processor 130 may acquire the evaluation values of each evaluation item from the server or database through the communication module 110. The range of evaluation values of the evaluation items can be set in various ways and may be normalized to enable comparison with other evaluation items as needed. The normalization may be performed before calculating the evaluation indicator.

The plurality of evaluation indicators and the plurality of evaluation items related to each of the plurality of evaluation indicators may be predefined. In the present embodiment, the evaluation indicator may be a value obtained by quantitatively evaluating the quality of the digital twins based on a specific attribute or perspective. The quality assurance index may be determined based on the plurality of evaluation indicators. In other words, the quality assurance index may be calculated based on the plurality of evaluation indicators and may be a value obtained by synthesizing the plurality of evaluation indicators. The plurality of evaluation items used to calculate the quality assurance index may be predefined. The evaluation indicator used to calculate the quality assurance index may vary depending on the development purpose, utilization plan, corresponding requirements, etc., of the target digital twin.

The evaluation item may be a detailed evaluation element used to calculate the evaluation indicator. The plurality of evaluation items related to each evaluation indicator may be predefined, and each evaluation indicator may be calculated based on the evaluation values of each of the plurality of evaluation items related to the corresponding evaluation indicator. The evaluation items related to each of the evaluation indicators may be defined based on the development purpose, utilization plan, and corresponding requirements of the target digital twin.

The evaluation indicators are evaluated independent of each other, and each evaluation indicator may be defined to prevent a specific evaluation indicator from influencing other evaluation indicators. The evaluation items are evaluated independent of each other, and each evaluation item may be defined to prevent the evaluation value of the specific evaluation item from influencing the evaluation values of other evaluation items. When the results of one evaluation item or its evaluation indicator influence the results of the other evaluation items or the other evaluation indicators, double evaluation may be performed. As a result, the objectivity of the quality evaluation of the digital twin may be compromised, and the interpretation of the evaluation results may become more complex. The present embodiment may ensure that each evaluation item and evaluation indicator is evaluated independently to improve the fairness of the evaluation of the digital twins, thereby ensuring that each evaluation indicator has a distinct meaning and value.

The digital twin targets various physical objects (e.g., automobiles, buildings, ships, cranes, containers, etc.) in various fields (e.g., environment, manufacturing, agriculture, transportation, etc.). The physical objects in each field have differences in terms of geometric models, structural models, and behavioral models. For the same physical objects, the shape and structural models may be similar, but the behavioral models may differ depending on the development purpose and utilization plan. For example, a digital twin for a human may have different muscle motion models, vascular motion models, joint motion models, etc. Since the targets and purposes of the digital twins vary, it is nearly impossible to establish uniform evaluation items and criteria that may be commonly applied to all the digital twins. For this reason, the evaluation items that determine the quality level of each evaluation indicator should be specifically defined for each evaluation target.

The plurality of evaluation items may include similarity, correspondence, and fidelity. In this embodiment, the similarity may be a value that indicates the degree to which the overall characteristics (features) between the physical object targeted by the digital twin and the digital twin are similar. The similarity may be a value indicating the degree to which the digital twin corresponds to the physical object based on the overall characteristics. The correspondence may be a value indicating the degree to which the specific elements of the digital twin correspond to the specific elements of the physical object. The correspondence may be a value indicating the degree to which the digital twin corresponds to the physical object based on the predefined specific elements. The fidelity may be a value that indicates the degree to which the detailed characteristics (features) between the digital twin and the physical object are similar. The fidelity may be a value that indicates how closely the digital twin corresponds to the physical object based on the detailed characteristics.

For example, fraternal twins may have high similarity because they resemble each other, but the correspondence may be low because certain items do not correspond, and the fidelity may also be low because the detailed characteristics are different. Conversely, identical twins may have high similarity and correspondence, but may have low fidelity because they differ in detailed characteristics, such as irises, fingerprints, and vascular patterns.

For example, when replicating a city road as a digital twin, the similarity may be evaluated based on the overall layout of roads and landmarks. The correspondence may be evaluated based on specific elements such as traffic lights, crosswalks, and intersections. The fidelity may be evaluated based on detailed elements such as a height of a building, a window configuration, texture of a building surface, specific locations of individual structures, and roadside trees. Therefore, the evaluation criteria for the similarity, correspondence, and fidelity should be established by a quality evaluation agency and a requester for quality evaluation according to the evaluation target, desired purpose, and requirements.

In various embodiments, the plurality of evaluation indicators may include composability, scalability, interoperability, multi-role capability, and real-time interaction. In this embodiment, the composability may be a value indicating the ease with which a specific digital twin may be composed from other digital twins. When a specific digital twin is generated by combining the plurality of digital twins (e.g., when digital twins of components (e.g., engine, brakes, steering wheel, etc.) are combined to generate a digital twin of an automobile), the composability may be considered. The scalability may be a value indicating the degree to which the digital twin may be easily scaled, and the interoperability may be a value that indicates the degree of ease of the interoperation with other systems or digital twins. The scalability and interoperability may be considered when different types of digital twins are configured to interoperate (e.g., a digital twin of an automobile interoperates with a digital twin of a city). Multi-role performance ability may be the result of evaluating a digital twin's ability to perform multiple roles. When the digital twin is configured to perform various roles (e.g., a digital twin of an ambulance should perform patient transport, parking, and driving functions), the multi-role performance ability may be considered. The real-time interoperation ability may be the result of evaluating the digital twin's ability to interoperate in real-time with a specific physical object (e.g., the physical object that is the target of the digital twin). The quality assurance index may be basically calculated based on the similarity, correspondence, and fidelity. Additional evaluation indicators may be flexibly applied depending on the development purpose of the corresponding digital twin.

When the plurality of evaluation indicators include the interoperability, the evaluation items related to the interoperability may include the number of supported physical communication interfaces, an interface conformance certification status, and the number of data service interface types.

FIG. 2 schematically illustrates how each evaluation indicator is calculated when the plurality of evaluation indicators include the similarity, correspondence, and fidelity. A similarity evaluation model 210 may calculate a similarity 211 based on evaluation values 213 of each of the plurality of evaluation items 212. A correspondence evaluation model 220 may calculate a correspondence 221 based on evaluation values 223 of each of the plurality of evaluation items 222. A fidelity evaluation model 230 may calculate fidelity 231 based on evaluation values 233 of each of the plurality of evaluation items 232. Here, each evaluation model may be a component responsible for a portion of the operation of the processor 130, and the operations performed by the evaluation model may be understood as operations performed by the processor 130.

The processor 130 may perform, for each of the plurality of evaluation indicators, an operation of calculating the indicator value of the target evaluation indicator based on the evaluation values of each of the plurality of evaluation items associated with the target evaluation indicator, thereby calculating the indicator values of each of the plurality of evaluation indicators and calculating the quality assurance index of the target digital twin based on the indicator values of each of the plurality of evaluation indicators.

The processor 130 may acquire configuration information regarding a representation form of the evaluation indicator, a representation form of the quality assurance index, whether to assign a weight to the evaluation item when calculating the evaluation indicator, and whether to assign a weight to the evaluation indicator when calculating the quality assurance index, and calculate the quality assurance index of the target digital twin in consideration of the configuration information. The configuration information may be generated in advance by the user, and the processor 130 may determine the representation form of the evaluation indicator, the representation form of the quality assurance index, whether to assign the weights to the evaluation items when calculating the evaluation indicator, and whether to assign the weights to the evaluation indicators when calculating the quality assurance index, depending on the configuration information acquired through the communication module 110. The user may generate configuration information in consideration of the development purpose, utilization plans, corresponding requirements, etc., of the target digital twin.

The indicator value of the evaluation indicator is expressed in either a first form in which the evaluation values of each of the plurality of evaluation items related to the evaluation indicator are listed, or a second form in which the evaluation values of each of the plurality of evaluation items related to the evaluation indicator are expressed as a unified representative value. The information indicating whether the evaluation indicator is to be expressed in either the first or second form may be included in the configuration information, and the processor 130 may determine the representation form of the evaluation indicator depending on the configuration information. The representation form of the evaluation indicator may be determined in consideration of the evaluation purpose, the nature of the evaluation target, the importance of the evaluation item, etc.

FIG. 3 illustrates a mathematical representation of the evaluation indicator for each form. As illustrated in FIG. 3, the similarity S may be expressed in a form (first form) in which evaluation values Sv.1, Sv.2, . . . , Sv.n of each of the related evaluation items Se.1, Se.2, . . . , Se.n are listed, or in a form (second form) in which the evaluation values Sv.1, Sv.2, . . . , Sv.n of each of the related evaluation items Se.1, Se.2, . . . , Se.n are unified (summed). The correspondence C and fidelity F may be expressed in the same manner as the similarity.

The quality assurance index may be expressed in either the first form, in which the indicator values of each of the plurality of evaluation indicators are listed, or the second form, in which the indicator values of each of the plurality of evaluation indicators are expressed as a unified representative value. The information indicating whether the quality assurance index is to be expressed in either the first or second form may be included in the configuration information, and the processor 130 may determine the representation form of the quality assurance index depending on the configuration information. The representation form of the quality assurance index may be determined in consideration of the evaluation purpose, the nature of the evaluation target, the importance of the evaluation item, etc.

When the weights need to be assigned to the evaluation items (i.e., when the configuration information is set to assign the weights to the evaluation items), the processor 130 may assign a predefined weight to each of the plurality of evaluation items related to the target evaluation indicator and calculate the indicator value of the target evaluation indicator based on the evaluation values to which the weights are assigned. The weights assigned to each of the plurality of evaluation items may be set differently. When the weights do not need to be assigned to the evaluation items (i.e., when the configuration information is set not to assign the weights to the evaluation items), the processor 130 may calculate the indicator value of the target evaluation indicator based on each of the plurality of evaluation items related to the target evaluation indicator.

The evaluation items may differ in their impact on the quality of the digital twin, and the impact of each evaluation item on the quality of the digital twin should be considered when evaluating the quality of the digital twin. This embodiment may evaluate the digital twin by individually assigning weight parameters to each evaluation item to allow for the evaluation of the digital twin in consideration of the impact of each evaluation item on the quality of the digital twin. The weights assigned to each evaluation item may be flexibly adjusted based on the development project purpose, the usage environment, the user requirements, etc., of the digital twin.

When the weight needs to be assigned to the evaluation indicator (i.e., when the configuration information is set to assign the weight to the evaluation indicator), the processor 130 may assign a predefined weight to the indicator values of each of the plurality of evaluation indicators and calculate the quality assurance index of the target digital twin based on the indicator values to which the weights are assigned. The weights assigned to each of the plurality of evaluation indicators may be set differently. When the weight does not need to be assigned to the evaluation indicator (i.e., when the configuration information is set not to assign the weight to the evaluation indicator), the processor 130 may calculate the quality assurance index of the target digital twin based on the indicator values of each of the plurality of evaluation indicators.

The evaluation indicators may differ in their impact on the quality of the digital twin, and the impact of each evaluation indicator on the quality of the digital twin should be considered when evaluating the quality of the digital twin. For example, when developing the digital twin of the physical object, if the development purpose of the digital twin is simply to provide a general understanding, rather than for critical issues like decision-making or safety management, the correspondence and fidelity should be considered with lower weight compared to the similarity when evaluating the quality of the digital twin. This embodiment may evaluate the digital twin by individually assigning weight parameters to each evaluation indicator to allow for the evaluation of the digital twin in consideration of the impact of each evaluation indicator on the quality of the digital twin. The weights assigned to each evaluation indicator may be flexibly adjusted based on the development project purpose, the usage environment, the user requirements, etc., of the digital twin.

For example, in the case of evaluating a digital twin of a ship, when replicating the overall appearance of the ship is crucial, the similarity may be assigned greater weights, and when the operation and stability of specific mechanical devices within the ship are crucial, the correspondence and fidelity may be assigned greater weights.

FIG. 4 illustrates a type of quality assurance indices according to conditions. Assuming that the representation forms of the quality assurance index and the evaluation indicator are identical, as illustrated in FIG. 4, the quality assurance index may be categorized into a total of eight types, depending on the representation forms of the evaluation indicator and the quality assurance index, whether to assign the weights to the evaluation items, and whether to assign the weights to the evaluation indicators.

When the quality assurance index is expressed in the first form, the processor 130 may list the plurality of evaluation indicators according to a preset listing order. The listing order may be preset by a user (e.g., a quality assurance operator). If a relevant standard specifies a listing order, the listing order of the plurality of evaluation indicators may be determined according to that standard. Each evaluation indicator may have a value of 0 or greater than 0, and a value of 0 for any evaluation indicator may indicate that the evaluation indicator is invalid. In other words, a value of 0 for any evaluation indicator may indicate that the quality of the digital twin has not been evaluated using that evaluation indicator. An evaluation indicator with a value greater than 0 may be valid on its own even when other evaluation indicators have a value of 0.

When it is necessary to express the evaluation indicator in the second form and it is not necessary to assign the weight to the evaluation item, the processor 130 may calculate the indicator value (representative value) of the target evaluation indicator based on at least one of a summed value, an arithmetic mean value, a geometric mean value, a harmonic mean value, a root mean square value, a minimum value, a maximum value, and an index mean of the evaluation values of each of the plurality of evaluation items related to the target evaluation indicator. The processor 130 may calculate the indicator value of the target evaluation indicator using any one of the mathematical methods described above, or may calculate the indicator value of the target evaluation indicator by combining two or more mathematical methods. However, the mathematical method of calculating the evaluation indicator is not limited to the above-described embodiments, and various well-known mathematical integration methods may be used to calculate the evaluation indicator.

A method of using a value obtained by summing the evaluation values of each of the plurality of evaluation items as the indicator value of the evaluation indicator (a simple sum method) is suitable when the absolute contribution of each evaluation item is important, the number of evaluation items is small, or the overall performance of the digital twin is important.

A method of using a value obtained by calculating the arithmetic mean of the evaluation values of each of the plurality of evaluation items as the indicator value of the evaluation indicator (an arithmetic mean method) is suitable when all the evaluation items are equally important, the number of evaluation items is large, or the overall performance of the digital twin is to be understood.

A method of using a value obtained by calculating the geometric mean of the evaluation values of each of the plurality of evaluation items (a value obtained by multiplying all the evaluation values and then taking an nth root of the value, where n is the number of evaluation values) as the indicator value of the evaluation indicator (a geometric mean method) is suitable when all the evaluation items should receive balanced high scores, or a low score of a specific evaluation item should have a significant impact on the overall result.

A method of using a value obtained by calculating the harmonic mean of the evaluation values of each of the plurality of evaluation items (a value obtained by calculating the arithmetic mean of the reciprocals of all the evaluation values and then taking the reciprocal of the mean) as the indicator value of the evaluation indicator (a harmonic mean method) is suitable when all evaluation items should meet minimum criteria or when the development of the digital twin is focused on improving its weak areas.

A method of using a value obtained by calculating the root mean square of the evaluation values of each of the plurality of evaluation items (a value obtained by calculating the arithmetic mean of the squares of the evaluation values and then taking the square root of the mean) as the indicator value of the evaluation indicator (a root mean square method) is suitable when aiming to highlight evaluation items with high quality performance or when dealing with data that exhibits high variability.

A method of using the minimum value among the evaluation values of the plurality of evaluation items as the indicator value of the evaluation indicator (a minimum value method) is suitable when all the evaluation items should meet a certain level or greater, or when the performance of the most vulnerable evaluation item determines the overall quality.

A method of using the maximum value of the evaluation values of the plurality of evaluation items as the indicator value of the evaluation indicator (a maximum value method) is suitable when excellence is required in any one area, or when the evaluation item with the highest quality performance can represent the overall quality.

A method of using a value obtained by calculating an index mean of the evaluation values of each of the plurality of evaluation items as the indicator value of the evaluation indicator (an index mean method) is suitable when higher scores are non-linearly assigned to the evaluation items showing high quality performance, when the value increase due to performance improvement is nonlinear, or when the evaluation items that are positioned at the top of the quality performance distribution are emphasized.

When it is necessary to express the evaluation indicator in the second form and it is necessary to assign the weight to the evaluation item, the processor 130 may calculate the indicator value (representative value) of the target evaluation indicator based on at least one of a weighted sum value, a weighted arithmetic mean value (including a simple weighted mean value and a normalized weighted arithmetic mean value), a weighted geometric mean value, and a weighted harmonic mean value of the evaluation values of each of the plurality of evaluation items related to the target evaluation indicator. The processor 130 may calculate the indicator value of the target evaluation indicator using any one of the mathematical methods described above, or may calculate the indicator value of the target evaluation indicator by combining two or more mathematical methods. However, the mathematical method for calculating the evaluation indicator is not limited to the above-described embodiments, and various well-known mathematical integration methods may be used to calculate the evaluation indicator.

A method of using a value obtained by calculating the weighted sum of the evaluation values of each of the plurality of evaluation items as the indicator value of the evaluation indicator (a weighted sum method) is suitable when the relative importance of each evaluation item is clear or when the impact of a specific evaluation item is to be emphasized.

A method of using a value obtained by calculating the weighted arithmetic mean of the evaluation values of each of the plurality of evaluation items as the indicator value of the evaluation indicator (a weighted arithmetic mean method) is suitable when the average performance of the digital twin needs to be understood in the situation where the importance of each evaluation item differs or when a consistent metric needs to be maintained in situations where the number of evaluation items may vary.

A method of using a value obtained by calculating the weighted geometric sum of the evaluation values of each of the plurality of evaluation items as the indicator value of the evaluation indicator (a weighted geometric mean method) is suitable in the case where balance among the evaluation items is required as in the case where the importance of each evaluation item differs or when the impact of a specific evaluation item is to be emphasized.

A method of using a value obtained by calculating the weighted harmonic mean of the evaluation values of each of the plurality of evaluation items as the indicator value of the evaluation indicator (a weighted harmonic mean method) is suitable when each evaluation item needs to meet minimum criteria in the situation where the importance of each evaluation item differs or when a specific evaluation item with low quality performance is to be emphasized.

In various embodiments, a value obtained by multiplying a deviation value (difference value from a preset target value) of the evaluation values of each of the plurality of evaluation items by individual weights may be used as the indicator value of the evaluation indicator. The weighted deviation method is suitable when specific goals are set for each evaluation item, or when both goal achievement and the quality of the digital twin should be considered simultaneously.

In various embodiments, the mathematical method of calculating the evaluation indicator may vary depending on the development stage of the digital twin. For example, in the initial development stage of the digital twin, the minimum value method may be used to verify that all the functions of the digital twin meet basic requirements. In later improvement stages, the root mean square method or the index mean method may be used to highlight the evaluation items with high quality performance when evaluating the digital twin. This embodiment allows for the evaluation of the quality of the digital twin more accurately and in accordance with the objects by calculating the evaluation indicator in various ways.

When the quality assurance index should be expressed in the second form and it is not necessary to assign the weight to the evaluation indicator, the processor 130 may calculate the quality assurance index of the target digital twin based on at least one of the summed value, arithmetic mean value, geometric mean value, harmonic mean value, root mean square value, minimum value, maximum value, and index mean value of the indicator values of each of the plurality of evaluation indicators. The processor 130 may calculate the quality assurance index using any one of the mathematical methods described above, or calculate the quality assurance index by combining two or more mathematical methods. However, the mathematical method of calculating the evaluation indicator is not limited to the above-described embodiments, and various well-known mathematical integration methods may be used to calculate the evaluation indicator.

When the quality assurance index should be expressed in the second form and it is necessary to assign the weight to the evaluation indicator, the processor 130 may calculate the quality assurance index of the target digital twin based on at least one of the weighted sum value, weighted arithmetic mean value, weighted geometric mean value, and weighted harmonic mean value of the indicator values of each of the plurality of evaluation indicators. The processor 130 may calculate the quality assurance index using any one of the mathematical methods described above, or calculate the quality assurance index by combining two or more mathematical methods. However, the mathematical method of calculating the evaluation indicator is not limited to the above-described embodiments, and various well-known mathematical integration methods may be used to calculate the evaluation indicator.

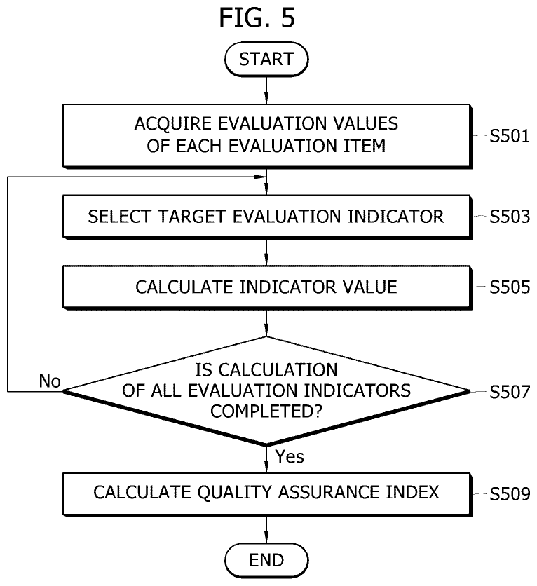

FIG. 5 is a flowchart illustrating a method of evaluating digital twins according to an embodiment of the present invention.

Hereinafter, referring to FIG. 5, the process of evaluating the target digital twin will be described focusing on the operation of the processor 130. Some of the operations to be described below may be performed in a different order from the order to be described below or omitted.

First, the processor 130 may acquire the evaluation values of each of the predefined evaluation items (S501). The processor 130 may acquire information about the evaluation values from a server or database storing the evaluation values of each of the predefined evaluation items via the communication module 110.

Next, the processor 130 may select a target evaluation indicator (S503). In operation S503, the processor 130 may select any one of the plurality of predefined evaluation indicators as the target evaluation indicator. In operation S503, the processor 130 may select the target evaluation indicator according to a predefined order.

Next, the processor 130 may calculate the indicator value of the target evaluation indicator based on the evaluation values of each of the plurality of evaluation items related to the target evaluation indicator (S505).

In operation S505, the processor 130 may acquire the configuration information regarding the representation form of the evaluation indicator and whether to assign the weight to the evaluation item when calculating the evaluation indicator, and calculate the indicator value of the target evaluation indicator in consideration of the acquired configuration information.

When the target evaluation indicator is the similarity, the evaluation indicator should be expressed in the first form, and it is not necessary to assign the weight to the evaluation item, the indicator value of the target evaluation indicator may be defined by the following Equation 1.

$$S = \{ Sv \text{.1} , Sv \text{.2} , … , Sv . n \} \qquad [ Equation 1 ]$$

Here, S denotes the similarity, and Sv.n denotes an evaluation value of an nth evaluation item.

When the target evaluation indicator is the similarity, the evaluation indicator should be expressed in the first form, and it is not necessary to assign the weight to the evaluation item, the indicator value of the target evaluation indicator may be defined by the following Equation 2.

$$S = \{ wSv \text{.1} * Sv \text{.1} , wSv \text{.2} * Sv \text{.2} , … , wSv . n * Sv . n \} \qquad [ Equation 2 ]$$

Here, wSv.n denotes the weight parameter assigned to the evaluation value of the nth evaluation item.

When the target evaluation indicator is the similarity, the evaluation indicator should be expressed in the second form, and it is not necessary to assign the weight to the evaluation item, the indicator value of the target evaluation indicator may be defined by the following Equation 3 or 4. Equation 3 defines the similarity when using the simple sum method, and Equation 4 defines the similarity when using the arithmetic mean method.

$$S = S v . 1 + S v \text{.2} + … + Sv . n \qquad [ Equation 3 ]$$

$$S = ( Sv \text{.1} + Sv \text{.2} + … + Sv . n ) / n \qquad [ Equation 4 ]$$

Here, n denotes the total number of related evaluation items.

When the target evaluation indicator is the similarity, the evaluation indicator should be expressed in the second form, and it is necessary to assign the weight to the evaluation item, the indicator value of the target evaluation indicator may be defined by the following Equation 5 or 6. Equation 5 defines the similarity when using the weighted sum method, and Equation 6 defines the similarity when using the weighted arithmetic mean method.

$$S = wSv \text{.1} * Sv \text{.1} + wSv \text{.2} * Sv \text{.2} + … + wSv . n * Sv . n \qquad [ Equation 5 ]$$

$$S = ( wSv \text{.1} * Sv \text{.1} + wSv \text{.2} * Sv \text{.2} + … + wSv . n * Sv . n ) / n \qquad [ Equation 6 ]$$

The correspondence and fidelity may also be defined in the same manner as in Equations 1 to 6 described above.

Next, the processor 130 may determine whether the indicator values of all the evaluation indicators have been calculated (S507). For example, assuming that the plurality of evaluation indicators include the similarity, the correspondence, and the fidelity, in operation S507, the processor 130 may determine whether the indicator values of the similarity, correspondence, and fidelity have been calculated.

When the indicator values are not calculated for all the evaluation indicators, the processor 130 may return to operation S503 and perform the process again from operation S503. In this case, the processor 130 may change the target evaluation indicator and perform the above-described process again.

On the other hand, when the indicator values are calculated for all the evaluation indicators, the processor 130 may calculate the quality assurance index of the target digital twin based on the indicator values of each of the plurality of evaluation indicators (S509).

In operation S509, the processor 130 may acquire the configuration information regarding the representation form of the evaluation indicator and whether to assign the weight to the evaluation item when calculating the quality assurance index, and calculate the indicator value of the target evaluation indicator in consideration of the acquired configuration information.

When the quality assurance index should be expressed in the first form and it is not necessary to assign the weight to the evaluation indicator, the quality assurance index may be defined by the following Equation 7.

$$QAI = \{ S , C , F , … \} \qquad [ Equation 7 ]$$

Here, QAI denotes the quality assurance index.

When the quality assurance index should be expressed in the first form and it is necessary to assign the weight to the evaluation indicator, the quality assurance index may be defined using Equation 8 below.

$$QAI = \{ {W}_{S} * S , {W}_{C} * C , {W}_{F} * F , … \} \qquad [ Equation 8 ]$$

Here, W_{S} denotes the similarity weight parameter, W_{C} denotes the correspondence weight parameter, and W_{F} denotes the fidelity weight parameter.

When the quality assurance index should be expressed in the second form and it is not necessary to assign the weight to the evaluation indicator, the quality assurance index may be defined using Equation 9 or Equation 10 below. Equation 9 defines the quality assurance index using the simple sum method, and Equation 6 defines the quality assurance index using the arithmetic mean method.

$$QAI = ( S + C + F + … ) \qquad [ Equation 9 ]$$

$$QAI = ( S + C + F + … ) / n \qquad [ Equation 10 ]$$

When the quality assurance index should be expressed in the second form and weights need to be applied to the evaluation indicators, the quality assurance index may be defined using Equation 11 or Equation 12 below. Equation 11 defines the quality assurance index using the weighted sum method, and Equation 12 defines the quality assurance index using the weighted arithmetic mean method.

$$QAI = ( {W}_{S} * S + {W}_{C} * C + {W}_{F} * F + … ) \qquad [ Equation 11 ]$$

$$QAI = ( {W}_{S} * S + {W}_{C} * C + {W}_{F} * F + … ) / n \qquad [ Equation 12 ]$$

As described above, it is possible to quantitatively and objectively evaluate the quality of the digital twins and provide the evaluation results to the user. In addition, according to the present invention, by evaluating the quality of the digital twin based on the clear and systematic criteria, it is possible to enhance the reliability of the evaluation results of the digital twin. In addition, according to the present invention, by adjusting the evaluation indicators used in evaluating the digital twins in accordance with the development purpose of the digital twins and the requirements of the project for developing the digital twins, it is possible to clearly verify whether the digital twins meet the expected objectives of the project client. In addition, according to the present invention, by calculating the evaluation indicators and quality assurance indices in various ways when evaluating the quality of the digital twins, it is possible to optimize the method of evaluating digital twins.

Although the present invention has been described with reference to embodiments shown in the accompanying drawings, they are only examples. It will be understood by those skilled in the art that various modifications and other equivalent exemplary embodiments are possible from the present invention. Accordingly, the technical scope of the present invention is to be determined by the spirit of the appended claims.

What is claimed is:

1. An apparatus for evaluating digital twins, comprising:
a memory configured to store at least one instruction; and
a processor configured to execute the at least one instruction stored in the memory,
wherein the processor acquires evaluation values of each evaluation item in a state in which a plurality of evaluation indicators and a plurality of evaluation items related to each of the plurality of evaluation indicators are defined, and calculates a quality assurance index, which is defined as an index quantitatively representing the quality of a target digital twin to be evaluated, based on the evaluation values of each evaluation item.

2. The apparatus of claim 1, wherein the processor performs, for each of the plurality of evaluation indicators, an operation of calculating an indicator value of the target evaluation indicator based on the evaluation values of each of the plurality of evaluation items related to the target evaluation indicator, and calculates the quality assurance index based on the indicator values of each of the plurality of evaluation items.

3. The apparatus of claim 2, wherein the plurality of evaluation indicators include a similarity representing a degree to which the target digital twin corresponds to the corresponding physical object based on overall characteristics, correspondence representing a degree to which the target digital twin corresponds to the physical object based on a specific element, and fidelity representing a degree to which the target digital twin corresponds to the physical object based on detailed characteristics.

4. The apparatus of claim 2, wherein the processor acquires configuration information regarding a representation form of the evaluation indicator, a representation form of the quality assurance index, whether to assign a weight to the evaluation item when calculating the evaluation indicator, and whether to assign a weight to the evaluation indicator when calculating the quality assurance index, and calculates the quality assurance index in consideration of the configuration information.

5. The apparatus of claim 4, wherein the indicator value of the evaluation indicator is expressed in either a first form in which the evaluation values of each of the plurality of evaluation items related to the evaluation indicator are listed, or a second form in which the evaluation values of each of the plurality of evaluation items related to the evaluation indicator are expressed as a unified representative value.

6. The apparatus of claim 5, wherein, when it is necessary to assign the weight to the evaluation item, the processor assigns a predefined weight to each of the plurality of evaluation items related to the target evaluation indicator and calculates an indicator value of the target evaluation indicator based on the evaluation values to which the weights are assigned.

7. The apparatus of claim 6, wherein, when it is necessary to express the evaluation indicator in the second form and it is necessary to assign the weight to the evaluation item, the processor calculates the indicator value of the target evaluation indicator based on at least one of a weighted sum, a weighted arithmetic mean, a weighted geometric mean, and a weighted harmonic mean of the evaluation values of each of the plurality of evaluation items related to the target evaluation indicator.

8. The apparatus of claim 6, wherein, when it is necessary to express the evaluation indicator in the second form and it is not necessary to assign the weight to the evaluation item, the processor calculates the indicator value of the target evaluation indicator based on at least one of a simple sum, an arithmetic mean, a geometric mean, a harmonic mean, a root mean square, a minimum value, a maximum value, and an index mean of the evaluation values of each of the plurality of evaluation items related to the target evaluation indicator.

9. The apparatus of claim 4, wherein the quality assurance index is expressed in either a first form in which the indicator values of each of the plurality of evaluation indicators are listed, or a second form in which the indicator values of each of the plurality of evaluation indicators are expressed as a unified representative value.

10. The apparatus of claim 9, wherein, when it is necessary to assign the weight to the evaluation indicator, the processor assigns a predefined weight to the indicator values of each of the plurality of evaluation indicators, and calculates the quality assurance index based on the indicator values to which the weights are assigned.

11. A method of evaluating digital twins, comprising:
acquiring, by a processor, evaluation values of each of a plurality of evaluation items in a state in which a plurality of evaluation indicators and a plurality of evaluation items related to each of the plurality of evaluation indicators are defined; and
calculating, by the processor, a quality assurance index defined as an index that quantitatively represents the quality of the target digital twin to be evaluated, based on the evaluation values of each evaluation item.

12. The method of claim 11, wherein, in the calculating of the quality assurance index, the processor performs, for each of the plurality of evaluation indicators, an operation of calculating an indicator value of the target evaluation indicator based on the evaluation values of each of the plurality of evaluation items related to the target evaluation indicator, and calculates the quality assurance index based on the indicator values of each of the plurality of evaluation items.

13. The method of claim 12, wherein the plurality of evaluation indicators include a similarity representing a degree to which the target digital twin corresponds to the corresponding physical object based on overall characteristics, correspondence representing a degree to which the target digital twin corresponds to the physical object based on a specific element, and fidelity representing a degree to which the target digital twin corresponds to the physical object based on detailed characteristics.

14. The method of claim 12, wherein, in the calculating of the quality assurance index, the processor obtains configuration information regarding a representation form of the evaluation indicator, a representation form of the quality assurance index, whether to assign a weight to the evaluation item when calculating the evaluation indicator, and whether to assign a weight to the evaluation indicator when calculating the quality assurance index, and calculates the quality assurance index in consideration of the configuration information.

15. The method of claim 14, wherein the indicator value of the evaluation indicator is expressed in either a first form in which the evaluation values of each of the plurality of evaluation items related to the evaluation indicator are listed, or a second form in which the evaluation values of each of the plurality of evaluation items related to the evaluation indicator are expressed as a unified representative value.

16. The method of claim 15, wherein, in the calculating of the quality assurance index, when it is necessary to assign the weight to the evaluation item, the processor assigns a predefined weight to each of the plurality of evaluation items related to the target evaluation indicator and calculates an indicator value of the target evaluation indicator based on the evaluation values to which the weights are assigned.

17. The method of claim 16, wherein, in the calculating of the quality assurance index, when it is necessary to express the evaluation indicator in the second form and it is necessary to assign the weight to the evaluation item, the processor calculates the indicator value of the target evaluation indicator based on at least one of a weighted sum, a weighted arithmetic mean, a weighted geometric mean, and a weighted harmonic mean of the evaluation values of each of the plurality of evaluation items related to the target evaluation indicator.

18. The method of claim 16, wherein, in the calculating of the quality assurance index, when it is necessary to express the evaluation indicator in the second form and it is not necessary to assign the weight to the evaluation item, the processor calculates the indicator value of the target evaluation indicator based on at least one of a simple sum, an arithmetic mean, a geometric mean, a harmonic mean, a root mean square, a minimum value, a maximum value, and an index mean of the evaluation values of each of the plurality of evaluation items related to the target evaluation indicator.

19. The method of claim 14, wherein the quality assurance index is expressed in either a first form in which the indicator values of each of the plurality of evaluation indicators are listed, or a second form in which the indicator values of each of the plurality of evaluation indicators are expressed as a unified representative value.

20. The method of claim 19, wherein, in the calculating of the quality assurance index, when it is necessary to assign the weight to the evaluation indicator, the processor assigns a predefined weight to the indicator values of each of the plurality of evaluation indicators, and calculates the quality assurance index based on the indicator values to which the weights are assigned.
